(19) United States
(12) Patent Application Publication
(10) Pub. No.: US 2005/0254209 A1
(43) Pub. Date: Nov. 17, 2005

(54) Computer casing with a heat-dissipating device

(76) Inventor: Hao-Cheng Lin, Taipei City (TW)

Correspondence Address: CAESAR, RIVISE, BERNSTEIN,;COHEN & POKOTILOW, LTD., 11TH FLOOR, SEVEN PENN CENTER, 1635 MARKET STREET, PHILADELPHIA, PA, 19103-2212, US

(21) Appl. No.: 10/844,030

(22) Filed: May 12, 2004

(51) Int. Cl. H05K 7/20

(52) U.S. Cl. 361/695

(57) ABSTRACT

A computer casing includes a case body and a heat-dissipating device. The case body has a side wall formed with a series of expansion slots. The heat-dissipating device is adapted for dissipating heat generated by a component inside the case body, and includes an impeller housing and a fan impeller. The impeller housing is mounted on the side wall inside the case body such that the impeller housing is juxtaposed with one of the expansion slots. The impeller housing is formed with an air inlet and an air outlet. The fan impeller is mounted in the impeller housing, and is operable so as to generate air currents that flow from the air inlet through the air outlet for cooling the component in the case body.

### BACKGROUND OF THE INVENTION

1. Field of the Invention

The invention relates to a computer casing, more particularly to a computer casing with a heat-dissipating device.

2. Description of the Related Art

Heat-dissipating devices for cooling a central processing unit (CPU) on a computer motherboard are known in the art. However, other components inside a computer casing, particularly expansion cards (such as VGA cards) mounted on expansion slots of the computer casing, also generate and accumulate large amounts of heat. Since the known heat-dissipating devices for cooling the CPU are not designed for cooling the expansion cards on the computer casing, cooling of the expansion cards is normally achieved by air circulation in the computer casing, which is insufficient to prevent overheating and breakdown of the expansion cards.

### SUMMARY OF THE INVENTION

Therefore, the object of the present invention is to provide a computer casing with a heat-dissipating device that is suitable for cooling expansion cards so as to overcome the aforesaid drawback associated with the prior art.

According to one aspect of the present invention, there is provided a computer casing that comprises a case body and a heat-dissipating device. The case body has a side wall formed with a series of expansion slots. The heat-dissipating device is adapted for dissipating heat generated by a component inside the case body. The heat-dissipating device includes an impeller housing and a fan impeller. The impeller housing is mounted on the side wall inside the case body such that the impeller housing is juxtaposed with one of the expansion slots. The impeller housing is formed with an air inlet and an air outlet. The fan impeller is mounted in the impeller housing, and is operable so as to generate air currents that flow from the air inlet through the air outlet for cooling the component in the case body.

According to another aspect of the present invention, there is provided a heat-dissipating device for a computer casing. The computer casing includes a case body having a side wall formed with a series of expansion slots, each of which has opposite first and second ends. The side wall is formed with a ledge that is disposed adjacent to the first ends of the expansion slots, and is further formed with a plurality of backplate retainers that are adjacent to the second ends of the expansion slots and that correspond respectively to the expansion slots. The heat-dissipating device is adapted for dissipating heat generated by a component inside the case body, and comprises an impeller housing and a fan impeller. The impeller housing has a first housing wall formed with an air inlet and adapted to be mounted on the side wall inside the case body such that the impeller housing is juxtaposed with one of the expansion slots. The first housing wall is further formed with an angled first leg to be disposed on the ledge, and a second leg configured to engage the backplate retainer that corresponds to the juxtapose done of the expansion slots. The impeller housing further has a second housing wall formed with an air outlet. The fan impeller is mounted in the impeller housing, and is operable so as to generate air currents that flow from the air inlet through the air outlet for cooling the component in the case body.

### BRIEF DESCRIPTION OF THE DRAWINGS

Other features and advantages of the present invention will become apparent in the following detailed description of the preferred embodiment with reference to the accompanying drawings, of which:

FIG. 1 is a fragmentary perspective view of the preferred embodiment of a computer casing according to the present invention;

FIG. 2 is a partly exploded, fragmentary perspective view of the preferred embodiment; and

FIG. 3 is a fragmentary, partly sectional, schematic side view of the preferred embodiment in an assembled state.

### DETAILED DESCRIPTION OF THE PREFERRED EMBODIMENT

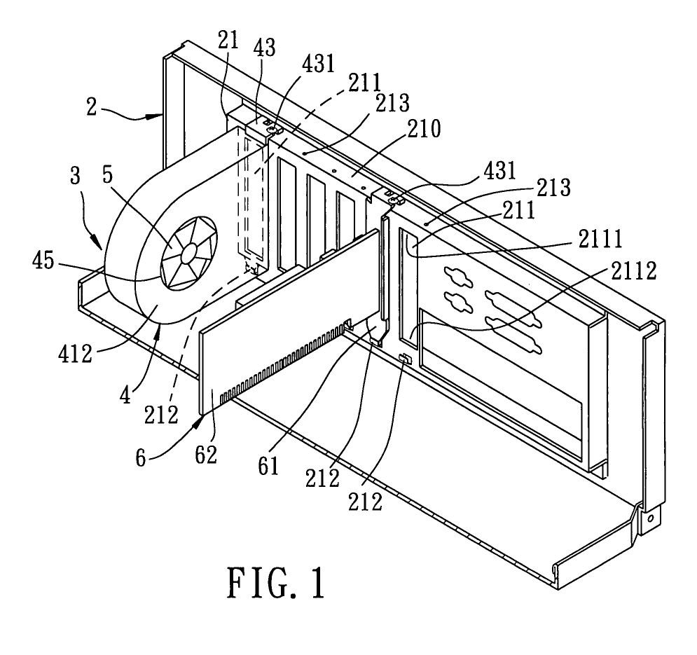

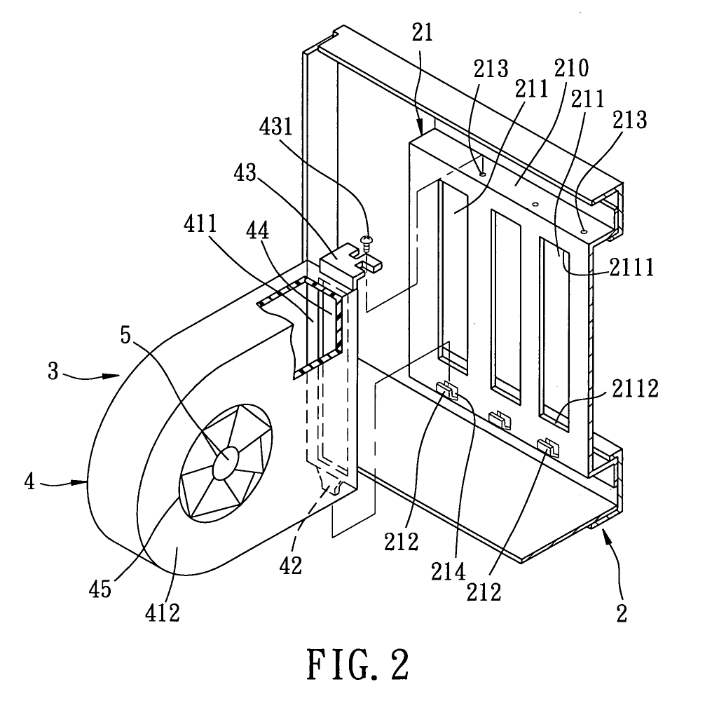

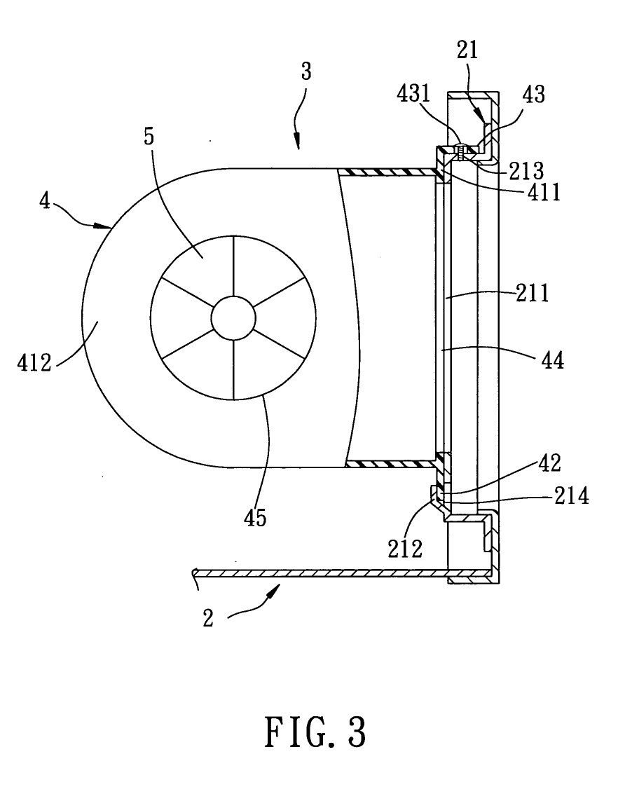

Referring to FIGS. 1 to 3, the preferred embodiment of a computer casing according to the present invention is shown to be adapted for dissipating heat generated by a component 6 that is mounted therein, and includes a case body 2 and a heat-dissipating device 3. As illustrated, the component 6 is an expansion card, such as a VGA card, a game card, etc., and includes a backplate 61 secured to the case body 2 in a conventional manner, and a circuit board 62 connected to the backplate 61.

The computer casing 2 of this embodiment is configured for application to a desktop computer, and has a rear side wall 21 that is punched to form a series of expansion slots 211. The expansion slots 211 have opposite first and second ends 2111, 2112. When the side wall 21 is punched, it is further formed with a ledge 210 that is disposed adjacent to the first (upper) ends 2111 of the expansion slots 211, and a plurality of backplate retainers 212 that are adjacent to the second (lower) ends 2112 of the expansion slots 211 and that correspond respectively to the expansion slots 211. In this embodiment, each of the backplate retainers 212 is an angled retainer that cooperates with the side wall 21 to form a retaining space 214. The ledge 210 is formed with a plurality of fastener holes 213 that correspond respectively to the expansion slots 211. When mounting the component 6 on the side wall 21, the backplate 61 is brought into alignment with a selected expansion slot 211, and an upper end of the backplate 61 is fastened to the ledge 210 using a screw 431 that engages the fastener hole 213 corresponding to the selected expansion slot 211, whereas a lower end of the backplate 61 is retained in the retaining space 214 of the backplate retainer 212 corresponding to the selected expansion slot 211.

The heat-dissipating device 3 includes an impeller housing 4 and a fan impeller 5. The impeller housing 4 is mounted on the side wall 21 inside the case body 2 such that the impeller housing 4 is juxtaposed with one of the expansion slots 211. In this embodiment, the impeller housing 4 has a first housing wall 411 mounted on the side wall 21 of the case body 2 and formed with an air inlet 44, and a second housing wall 412 transverse to the first housing wall 411 and formed with an air outlet 45. The first housing wall 411 is further formed with an angled first leg 43 to be disposed on the ledge 210, and a second leg 42 to engage the backplate retainer 212 that corresponds to the juxtaposed one of the expansion slots 211. A screw fastener 431 engages the fastener hole 213 that corresponds to the juxtaposed one of the expansion slots 211 for fastening the first leg 43 to the ledge 210.

The fan impeller 5 is mounted in the impeller housing 4, and is operable so as to generate air currents that flow from the air inlet 44 through the air outlet 45, thereby cooling the component 6 in the case body 2.

Because the heat-dissipating device 3 is disposed in the case body 2 such that cooling air is blown directly toward the component 6, the cooling effect can be optimized to avoid overheating of the component 6.

Moreover, since the heat-dissipating device 3 is conveniently mounted in the case body 2 in a manner similar to the mounting of the expansion card 6, it is possible to use the case body 2 having a conventional configuration when implementing the present invention.

Based on actual test results, under a room temperature of 20° C., the temperature of the component 6 reached 45° C. thirty minutes after a computer is turned on when the heat-dissipating device 3 is deactivated. However, upon operation of the heat-dissipating device 3 at impeller speeds of 2000, 2500 and 3000 RPM, the temperature of the component 6 is lowered to 35° C., 34° C. and 32° C., respectively.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

1. A computer casing comprising:
a case body having a side wall formed with a series of expansion slots; and
a heat-dissipating device adapted for dissipating heat generated by a component inside said case body, said heat-dissipating device including
an impeller housing mounted on said side wall inside said case body such that said impeller housing is juxtaposed with one of said expansion slots, said impeller housing being formed with an air inlet and an air outlet, and
a fan impeller mounted in said impeller housing and operable so as to generate air currents that flow from said air inlet through said air outlet for cooling the component in said case body.

2. The computer casing as claimed in claim 1, wherein said impeller housing has a first housing wall mounted on said side wall of said case body and formed with said air inlet, and a second housing wall formed with said air outlet.

3. The computer casing as claimed in claim 2, wherein said second housing wall is transverse to said first housing wall.

4. The computer casing as claimed in claim 2, wherein said expansion slots have opposite first and second ends, said side wall being formed with a ledge that is disposed adjacent to said first ends of said expansion slots, said side wall being further formed with a plurality of backplate retainers that are adjacent to said second ends of said expansion slots and that correspond respectively to said expansion slots.

5. The computer casing as claimed in claim 4, wherein said first housing wall is further formed with an angled first leg to be disposed on said ledge, and a second leg to engage said backplate retainer that corresponds to the juxtaposed one of said expansion slots.

6. The computer casing as claimed in claim 5, further comprising a screw fastener for fastening said first leg to said ledge.

7. A heat-dissipating device for a computer casing, the computer casing including a case body having a side wall formed with a series of expansion slots, the expansion slots having opposite first and second ends, the side wall being formed with a ledge that is disposed adjacent to the first ends of the expansion slots, the side wall being further formed with a plurality of backplate retainers that are adjacent to the second ends of the expansion slots and that correspond respectively to the expansion slots,
said heat-dissipating device being adapted for dissipating heat generated by a component inside the case body, and comprising:
an impeller housing having a first housing wall formed with an air inlet and adapted to be mounted on the side wall inside the case body such that said impeller housing is juxtaposed with one of the expansion slots, said first housing wall being further formed with an angled first leg to be disposed on the ledge, and a second leg configured to engage the backplate retainer that corresponds to the juxtaposed one of the expansion slots, said impeller housing further having a second housing wall formed with an air outlet; and
a fan impeller mounted in said impeller housing and operable so as to generate air currents that flow from said air inlet through said air outlet for cooling the component in the case body.

8. The heat-dissipating device as claimed in claim 7, wherein said second housing wall is transverse to said first housing wall.

9. The heat-dissipating device as claimed in claim 7, further comprising a screw fastener adapted for fastening said first leg to the ledge.
